(19) United States
(12) Patent Application Publication
(10) Pub. No.: US 2015/0255442 A1
(43) Pub. Date: Sep. 10, 2015

(54) POWER SEMICONDUCTOR MODULE

(71) Applicant: KABUSHIKI KAISHA TOSHIBA, Tokyo (JP)

(72) Inventor: Hiroshi Matsuyama, Nomi-shi (JP)

(21) Appl. No.: 14/336,890

(22) Filed: Jul. 21, 2014

(30) Foreign Application Priority Data
Mar. 10, 2014 (JP) 2014-046224

(51) Int. Cl. H01L 25/18; H01L 23/538; H01L 23/522; H01L 29/739; H01L 29/861

(52) U.S. Cl. CPC H01L 25/18; H01L 29/7393; H01L 29/861; H01L 23/5228; H01L 23/5386

(57) ABSTRACT

According to one embodiment, a power semiconductor module includes a substrate, a first interconnection layer, semiconductor elements, and a rectifier element. The first interconnection layer is provided on the substrate. The semiconductor elements are provided on the first interconnection layer. Each of the semiconductor elements includes first, second, and third electrodes. The second electrode is electrically connected to the first interconnection layer. The rectifier element is provided on the first interconnection layer, and includes a fifth electrode electrically connected to the first interconnection layer and a fourth electrode electrically connected to the first electrode. The semiconductor elements and the rectifier elements are radially disposed on the first interconnection layer. Arbitrary points fallen in respective regions of the semiconductor elements and an arbitrary point fallen in a region of the rectifier element are disposed in point symmetry or line symmetry based on the first point.

### CROSS-REFERENCE TO RELATED APPLICATIONS

This application is based upon and claims the benefit of priority from Japanese Patent Application No.2014-046224, filed on Mar. 10, 2014; the entire contents of which are incorporated herein by reference.

### FIELD

Embodiments described herein relate generally to a power semiconductor module.

### BACKGROUND

In power semiconductor modules, high breakdown voltage and a large current are achieved by connecting in parallel an insulated gate bipolar transistor (IGBT) element and a fast recovery diode (FRD) element mounted on a substrate.

However, connecting them in parallel allows a number of loops to be formed in a circuit, and each loop has a unique resonance frequency, respectively. If an operating frequency of the IGBT element and the resonance frequency of any loop match, the power semiconductor module itself becomes an oscillator, and the gate control of the IGBT element may be negatively affected.

### BRIEF DESCRIPTION OF THE DRAWINGS

FIG. 1A is a schematic plan view of a power semiconductor module according to the first embodiment, and FIG. 1B is a schematic cross-sectional view of the A-A′ line in FIG. 1A;

FIG. 2 is a schematic plan view illustrating an element disposal region of the power semiconductor module according to the first embodiment;

FIG. 3A and FIG. 3B are schematic plan views of a power semiconductor module according to the reference example;

FIG. 4 is a diagram illustrating an equivalent circuit of the power semiconductor module according to the reference example;

FIG. 5 is a diagram showing a gate-emitter voltage, a collector current, and a collector-emitter voltage according to the reference example;

FIG. 6A is a diagram illustrating the operation of the power semiconductor module according to the first embodiment, and FIG. 6B is a diagram illustrating an equivalent circuit of the power semiconductor module according to the first embodiment;

FIG. 7 is a schematic plan view of a power semiconductor module according to a variation of the first embodiment;

FIG. 8A is a schematic plan view of a power semiconductor module according to the second embodiment, and FIG. 8B is a schematic plan view of the power semiconductor module according to the second embodiment;

FIG. 9A is a schematic plan view of a power semiconductor module according to the third embodiment, FIG. 9B is a schematic plan view of the power semiconductor module according to the third embodiment, and FIG. 9C is a schematic plan view of the power semiconductor module according to the third embodiment;

FIG. 10A is a schematic plan view of a power semiconductor module according to the fourth embodiment, and FIG. 10B is a schematic plan view of the power semiconductor module according to the fourth embodiment; and

FIG. 11A is a schematic plan view of a power semiconductor module according to the fifth embodiment, and FIG. 11B is a schematic plan view of the power semiconductor module according to the fifth embodiment.

### DETAILED DESCRIPTION

According to one embodiment, a power semiconductor module includes a substrate, a first interconnection layer, a plurality of semiconductor elements, and a rectifier element. The first interconnection layer is provided on the substrate. The semiconductor elements are provided on the first interconnection layer. Each of the semiconductor elements includes a first electrode, a second electrode, and a third electrode. The second electrode is electrically connected to the first interconnection layer. The rectifier element is provided on the first interconnection layer, and includes a fifth electrode electrically connected to the first interconnection layer and a fourth electrode electrically connected to the first electrode. The semiconductor elements and the rectifier elements are radially disposed on the first interconnection layer from an arbitrary first point in the substrate. Arbitrary points fallen in respective regions of the semiconductor elements are disposed in point symmetry or line symmetry based on the first point. An arbitrary point fallen in a region of the rectifier element is disposed in point symmetry or line symmetry based on the first point.

Various embodiments will be described hereinafter with reference to the accompanying drawings. In the following description, the same reference numeral is applied to the same member, and for members that have been described once, the description is omitted as appropriate.

### FIRST EMBODIMENT

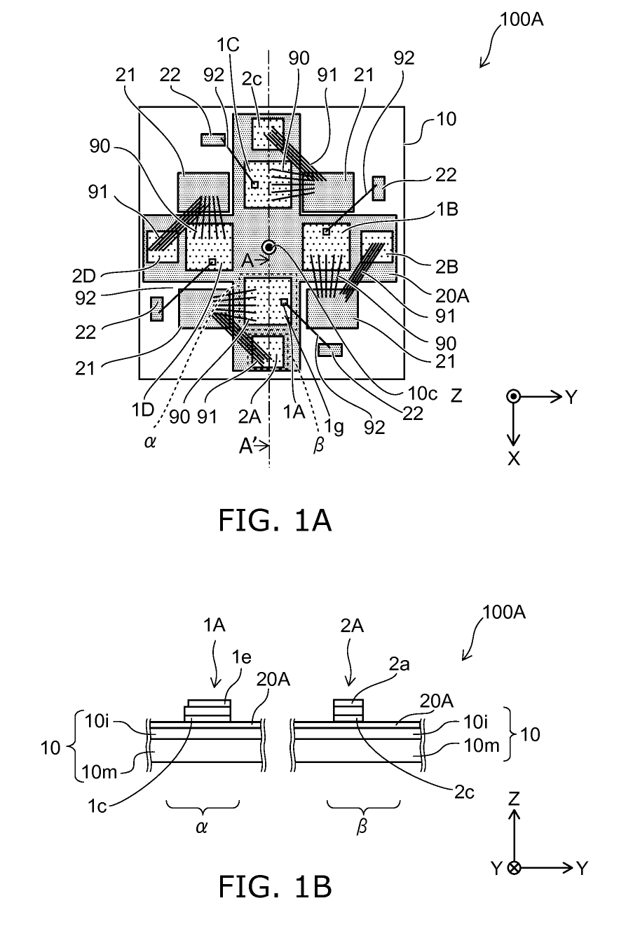

FIG. 1A is a schematic plan view of a power semiconductor module according to the first embodiment, and FIG. 1B is a schematic cross-sectional view of the A-A′ line in FIG. 1A. Here, FIG. 1B illustrates semiconductor chips in regions α and β.

A substrate 10 that is a support base body of a power semiconductor module 100 A is provided with a metal plate 10m and an insulating layer 10i. The substrate 10 may also be referred to as an insulating substrate.

An interconnection layer 20A (first interconnection layer) is provided on the substrate 10. The interconnection layer 20A is an interconnection pattern that includes, for example, copper (Cu) and the like.

A plurality of switching elements (semiconductor elements) is provided on the interconnection layer 20A. The switching elements are, for example, IGBT elements. The switching elements may also be MOSFETs. For example, each of four switching elements 1A to 1D is provided with an emitter electrode 1e (first electrode), a collector electrode 1c (second electrode), and a gate electrode 1g (third electrode). Each of the collector electrodes 1c of the switching elements 1A to 1D is electrically connected to the interconnection layer 20A. Each of the gate electrodes 1g of the switching elements 1A to 1D is connected to an interconnection layer 22 via a wire 92. The wire 92 and the interconnection layer 22 are electrically connected by, for example, soldering.

Rectifier elements 2A to 2D are also provided on the interconnection layer 20A. The rectifier elements are, for example, FRD elements. Each of the rectifier elements 2A to 2D is connected in parallel with each of the collector electrodes 1c and the emitter electrodes 1e of the switching elements 1A to 1D.

Each of the rectifier elements 2A to 2D has an anode electrode 2a (fourth electrode) and a cathode electrode 2c (fifth electrode). The cathode electrode 2c is electrically connected to the interconnection layer 20A. The anode electrode 2a is electrically connected to the emitter electrode 1e via wires 90, an interconnection layer 21, and wires 91.

Note that, in the first embodiment, the interconnection layer 20A may be referred to as a collector pattern, and the interconnection layer 21 may be referred to as an emitter pattern.

A configuration when the switching elements 1A to 1D and the rectifier elements 2A to 2D connected in parallel to each of the switching elements 1A to 1D are viewed from a direction perpendicular to the substrate 10 (for example, Z-direction) is described below. Here, an arbitrary point in the substrate 10, for example a center point 10c (first point), is selected.

The switching elements 1A to 1D are disposed radially from the center point 10c. Each of the rectifier elements 2A to 2D is disposed radially from the center point 10c. Distances from the center point 10c to each of the switching elements 1A to 1D are substantially equivalent. Also, distances from the center point 10c to each of the rectifier elements 2A to 2D are substantially equivalent.

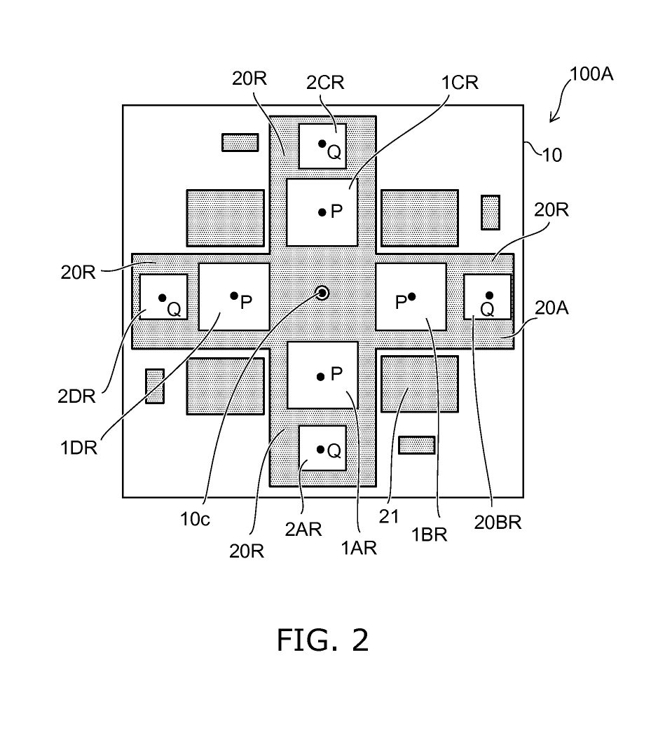

FIG. 2 is a schematic plan view illustrating an element disposal region of the power semiconductor module according to the first embodiment.

When viewing the interconnection layer 20A from the Z-direction, the interconnection layer 20A is cross-shaped.

With the power semiconductor module 100A, an arbitrary point P is selected in each of regions 1AR to 1DR on which each of the plurality of switching elements is disposed. The arbitrary points P fallen in each of the regions 1AR to 1DR are disposed in point symmetry from the center point 10c. Further, an arbitrary point Q is selected in each of regions 2AR to 2DR on which each of the plurality of rectifier elements 2A to 2D is disposed. The arbitrary points Q fallen in each of the regions 2AR to 2DR are disposed in point symmetry from the center point 10c. Note that the points P may be center points of each of the regions 1AR to 1DR. The points Q may be center points of each of the regions 2AR to 2DR.

With the power semiconductor module 100A, the interconnection layer 20A extends in four directions from the center point 10c in a cross-shape. Four switching elements 1A to 1D are provided on each region 20R extending from the center point 10c. Further, when a direction expanding radially from the center point 10c is defined as an outer side of the power semiconductor module 100A, the rectifier elements 2A to 2D are provided on the respective outer sides of the four switching elements 1A to 1D.

Prior to describing an operation of the power semiconductor module 100A, an operation of a power semiconductor module according to a reference example will be described.

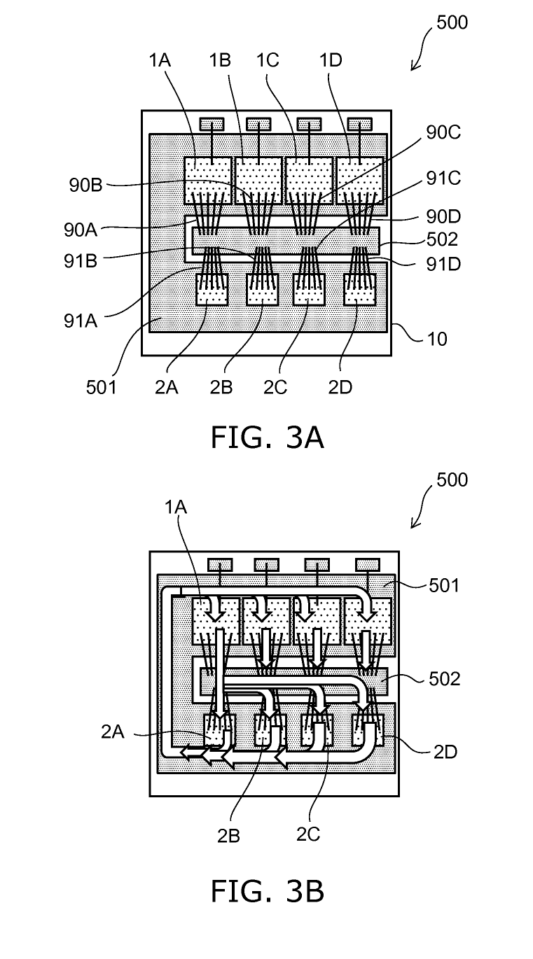

FIG. 3A and FIG. 3B are schematic plan views of a power semiconductor module according to the reference example.

With a power semiconductor module 500 illustrated in FIG. 3A, a planar shape of an interconnection layer 501 is U-shaped, and a group of the plurality of switching elements 1A to 1D and a group of the plurality of rectifier elements 1A to 1D are provided facing each other on the interconnection layer 501. An interconnection layer 502 is provided between the group of the plurality of switching elements 1A to 1D and the group of the plurality of rectifier elements 2A to 2D.

Here, the emitter electrode 1e of the switching element 1A is electrically connected to the anode electrode 2a of the rectifier element 2A via wires 90A, the interconnection layer 502, and wires 91A. The emitter electrode 1e of the switching element 1B is electrically connected to the anode electrode 2a of the rectifier element 2B via wires 90B, the interconnection layer 502, and wires 91B. The emitter electrode 1e of the switching element 1C is electrically connected to the anode electrode 2a of the rectifier element 2C via wires 90C, the interconnection layer 502, and wires 91C. The emitter electrode 1e of the switching element 1D is electrically connected to the anode electrode 2a of the rectifier element 2D via wires 90D, the interconnection layer 502, and wires 91D.

FIG. 3B illustrates a state of a tail current after turnoff in the reference example.

When a potential equal to or greater than a threshold value is applied to the gate electrode 1g of the IGBT element, the IGBT element is turned on, and current flows from the collector side to the emitter side. At this time, an electron hole (hole) is implanted in a drift layer from a p⁺ layer on the collector side. Therefore, a conduction modulation occurs in the drift layer, the drift layer becomes a layer with low resistance, and a large current flows between the collector and the emitter.

Meanwhile, immediately after the turnoff of the IGBT element, a space charge layer (depletion layer) with a thickness (W) changing due to voltage applied to the collector side begins to be formed on the drift layer of the IGBT element. Furthermore, when the IGBT element is turned off, the electron hole implantation into the drift layer from the p⁺ layer is suspended. However, a large number of implanted electron holes remain in the drift layer.

Subsequently, when the voltage between the collector and the emitter rises, the electron holes remaining in the drift layer are moved to the emitter side. This phenomenon means that the collector current flows again according to the rising of voltage between the collector and the emitter. This current is the tail current of the IGBT element. For example, with the switching element 1A, the tail current flows in the loop shaped paths of the switching element 1A, the interconnection layer 502, the rectifier element 2A, and the interconnection layer 501.

However, with the element disposition illustrated in FIG. 3A, for example, the emitter electrode 1e of the switching element 1A is also electrically connected to the anode electrode 2a of the rectifier element 2B via the wire 90A, the interconnection layer 502, and the wire 91B. Also, the emitter electrode 1e of the switching element 1A is electrically connected to the anode electrode 2a of the rectifier element 2C via the wire 90A, the interconnection layer 502, and the wire 91C. Furthermore, the emitter electrode 1e of the switching element 1A is electrically connected to the anode electrode 2a of the rectifier element 2D via the wire 90A, the interconnection layer 502, and the wire 91D.

Therefore, the tail current caused by the switching element 1A can flow into four loops. This phenomenon is schematically illustrated using an arrow in FIG. 3B.

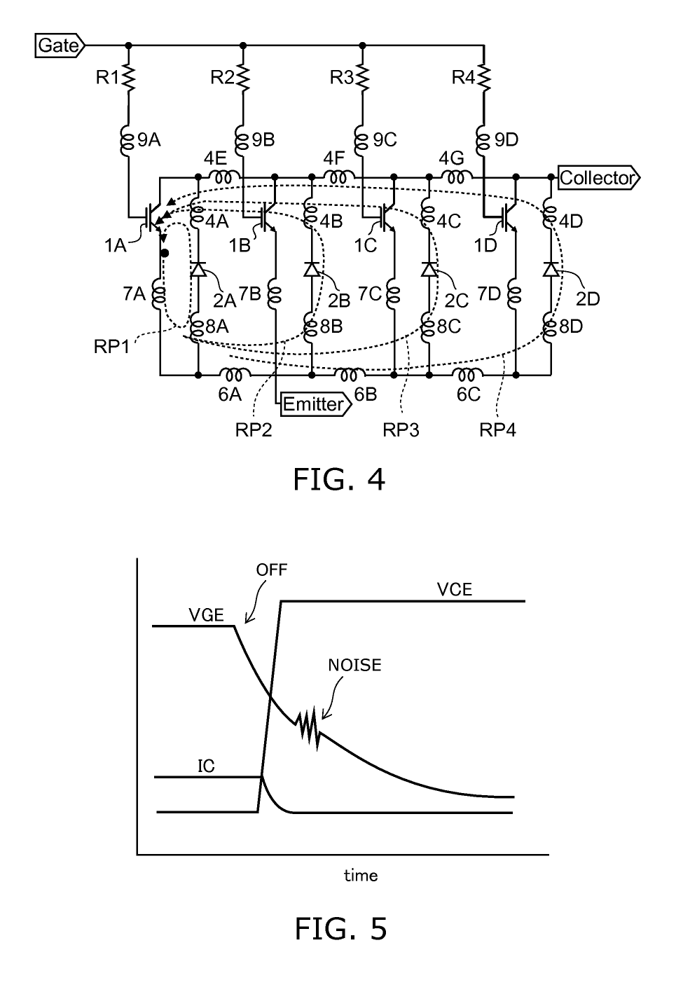

FIG. 4 is a diagram illustrating an equivalent circuit of the power semiconductor module according to the reference example.

Here, in the equivalent circuit, inductance and resistance brought about by the wire, the interconnection layer, and the like in the power semiconductor module 500 are illustrated as inductance 7A to 7D, 8A to 8D, 9A to 9D, 4A to 4G, 6A to 6G, and resistance R1 to R4.

During the period that the tail current of the IGBT element occurs (hereinafter, referred to as the tail period), an electron hole travels in the space charge layer. At this time, the IGBT element operates as a negative resistance. The operating frequency of the IGBT element when operating as a negative resistance can be found by adding a delay time for the electron hole implantation and an electron hole traveling time obtained by integrating the reciprocal of the drift velocity of the electron hole by the thickness (W) of the space charge layer and obtaining the reciprocal of the added value.

When this calculated frequency matches the parallel resonance frequency of a resonant circuit formed by the interconnection inside the power semiconductor module, the power semiconductor module oscillates as a negative resistance oscillator. This oscillation has a specific frequency distribution according to differences in the structure of the elements, the size of the elements, the material of the elements, and the like. However, this oscillation becomes a noise source.

FIG. 5 is a diagram showing a gate-emitter voltage, a collector current, and a collector-emitter voltage according to the reference example.

For example, when turning off the gate-emitter voltage VGE, the collector-emitter voltage VCE rises. Therefore, a collector current IC forms a tail inside the IGBT element. However, noise is generated in the gate-emitter voltage VGE. When this type of noise is generated, controllability of the gate electrode of the IGBT element becomes worse.

In the reference example, four loops RP1 to RP4 are formed by one switching element thereby making a total of 16 loops formed on the power semiconductor module 500.

These 16 loops form each of the LC circuits, and each have a unique resonance frequency. When the frequency distribution of a noise signal of the IGBT element matches the resonance frequency of at least one of the 16 loops of the power semiconductor module 500, the noise signal of the IGBT element is significantly amplified. In other words, there are many resonance points of the LC resonance frequency, and the broader the frequency band of the noise signal of the IGBT element, the higher the probability of matching becomes.

For example, for wires, the wire inductance values are identical if the lengths of the wires are identical. However, for the loops RP1 to RP4, the tail currents have different lengths passing through the interconnection layer 502, and therefore differences in respective inductance caused by the interconnection layer 502 occurs. This value, becomes an inductance ratio of an integer multiple because the approximate pass through length becomes an integer multiple.

Similarly, differences in inductance caused by the interconnection layer 501 also occur, and this becomes an inductance ratio of an integer multiple. As a result, the total inductance of each of the 16 loops is all different, and become values within a range of approximately several nH to several tens of nH.

Here, a resonance frequency f is f=1/(2π•square root of (L•C)), and L is 16, the number of resonance frequencies therefore becomes at least 16 or more. Furthermore, a capacitance C of the IGBT element and the FRD element fluctuates according to product bias conditions, i.e., CV characteristics (the higher the voltage, the lower C is). Thereby, the above 16 resonance frequencies also fluctuate in accordance with the bias conditions.

Supposing that L is from 1 nH to 16 nH, and capacitance C is from 500 pF to 100 pF, the resonance frequency becomes from 16 nH to 1 nH for a total of 16 conditions at from 56 MHz to 225 MHz when the capacitance C is 500 pF, a total of 16 conditions at from 126 MHz to 503 MHz when the capacitance is 100 pF, thereby making oscillation possible across a wide band from 50 MHz to 500 MHz.

The noise frequency emitted from IGBT element, has a tendency to transfer in the high frequency direction as the substrate gets thinner. On the other hand, the number of loaded FRD elements and IGBT elements increases to correspond to the high breakdown voltage and large current of the power semiconductor module. In other words, the number of LC routes in the power semiconductor module also increases. In addition, the range of the capacitance C expands in conjunction with a higher breakdown voltage. Therefore, it is desired to reduce the C, L combination to prevent turnoff oscillation.

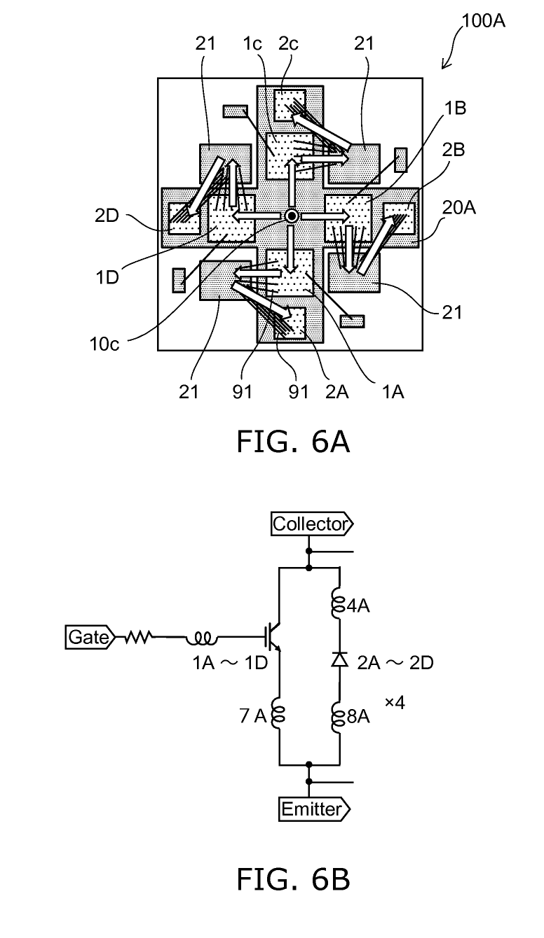

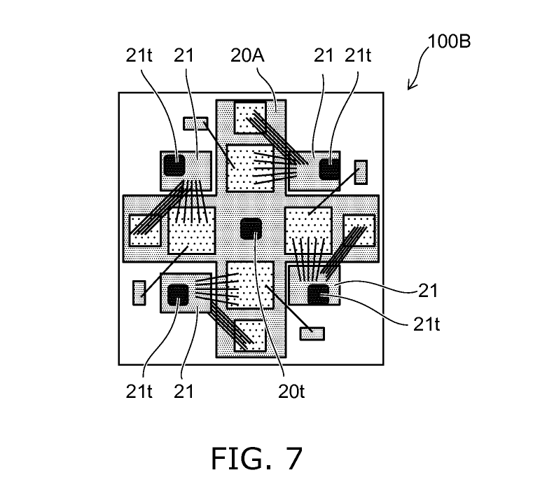

FIG. 6A is a diagram illustrating the operation of the power semiconductor module according to the first embodiment, and FIG. 6B is a diagram illustrating an equivalent circuit of the power semiconductor module according to the first embodiment.

In FIG. 6A, the flow of the tail current is illustrated by an arrow.

With the power semiconductor module 100A, the inductance of each wire is the same because the length of each wire is the same. Further, each of the interconnection layers 21 has the same shape, the same size, and the same inductance. Furthermore, the interconnection layer 20A is patterned in point symmetry with the center point 10c as the center. Therefore, in each of the plurality of switching elements 1A to 1D, the inductance of the route in which the collector current flows is the same.

As a result, as illustrated in FIG. 6B, the four loops configured with the same equivalent circuit are connected in parallel in the power semiconductor module 100A. Here, the inductance of each of the loops is the same value.

The resonance frequency f of the power semiconductor module 100A is; f=1/(2π•square root of (L•C)), and there is only one combination of L. However, the capacitance C of the IGBT element and the FRD element fluctuate according to the product bias conditions, or in other words, the C•V characteristics. Therefore, the bias conditions fluctuate relative to the single L. Supposing that L changes to 5 nH, and the capacitance C changes from 500 pF to 100 pF, the resonance frequency is 5 nH for a total of one condition at 101 MHz when the capacitance is 500 pF, and a total of one condition at 225 MHz when the capacitance is 100 pF. That is to say, the oscillation frequency is from approximately 101 MHz and 225 MHz thereby reducing the oscillation conditions to 1/16, reducing the range of the oscillation frequency by nearly half, and significantly reducing oscillation probability compared to the reference example. Therefore, the turnoff oscillation is reliably suppressed. Note that even when the number of switching elements is greater than 4, the same effect can be obtained by adding in the same manner the patterns of the interconnection layers 20A and 21 with the center point 10c as a start point. Conversely, even when the number is 2 or 3, the same effect can be obtained by patterning in the same manner the patterns of the interconnection layers 20A and 21 with the center point 10c as a start point.

FIG. 7 is a schematic plan view of a power semiconductor module according to a variation of the first embodiment.

An electrode terminal 21t may be provided on the interconnection layer 21 as in the power semiconductor module 100B illustrated in FIG. 7. Here, by symmetrically designing the shape and size of the electrode terminal 21t, the inductance that connects the emitters becomes the same. Moreover, the electrode terminal 20t may be provided at the position of the center point 10c of the interconnection layer 20A.

Note that the configuration where the pattern of the interconnection layer, the disposed positions of each of the switching elements 1A to 1D, the disposed positions of each of the rectifier elements 2A to 2D, and the disposed positions of the wires 90 and 91 are disposed in point symmetry or line symmetry with the center point 10c, is not limited to the first embodiment. A variation of the first embodiment is described below.

### SECOND EMBODIMENT

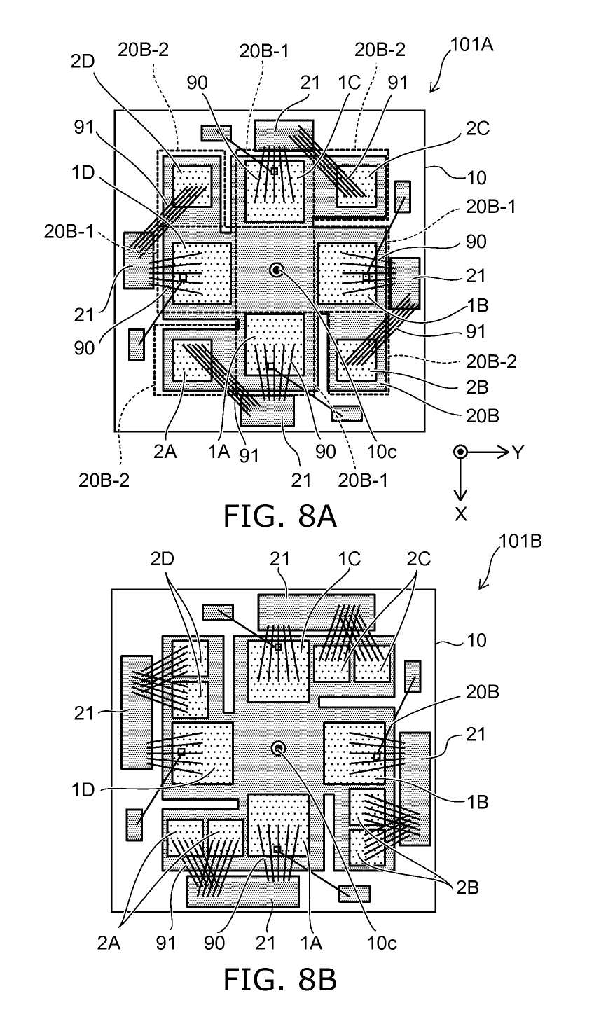

FIG. 8A is a schematic plan view of a power semiconductor module according to the second embodiment, and FIG. 8B is a schematic plan view of the power semiconductor module according to the second embodiment.

In a power semiconductor module 101A illustrated in FIG. 8A, when viewing an interconnection layer 20B from the Z-direction, the interconnection layer 20B has a first region 20B-1 extending in four directions from the center of the interconnection layer 20B and a second region 20B-2 that extends even further from the first region 20B-1. When viewing the interconnection layer 20B from the Z-direction, the first region 20B-1 and the second region 20B-2 configure an L shape.

In the power semiconductor module 101A, each of the four switching elements 1A to 1D is provided on the first region 20B-1. Each of rectifier elements 2A to 2D is provided on the second region 20B-2.

Even in this type of configuration, noise generation is suppressed by an operation similar to that as the first embodiment. Further, in the power semiconductor module 101A, each of the rectifier elements 2A to 2D is not disposed on the outer side of each of the switching elements 1A to 1D. Therefore, the size of the power semiconductor module is reduced.

Furthermore, in the power semiconductor module 101A, because each element of the switching elements 1A to 1D and the rectifier elements 2A to 2D is disposed on the substrate 10 in a grid pattern, heat generated during operation is dissipated and the temperature within the power semiconductor module becomes more uniform.

Note that it is not necessary for only one rectifier element to be connected in parallel to one switching element.

For example, as in a power semiconductor module 101B illustrated in FIG. 8B, a plurality of rectifier elements may be connected in parallel to one switching element. Note that the number of rectifier elements connected in parallel to one switching element is the same number on each switching element. Even in this type of configuration, noise generation is suppressed by an operation similar to that as the first embodiment.

### THIRD EMBODIMENT

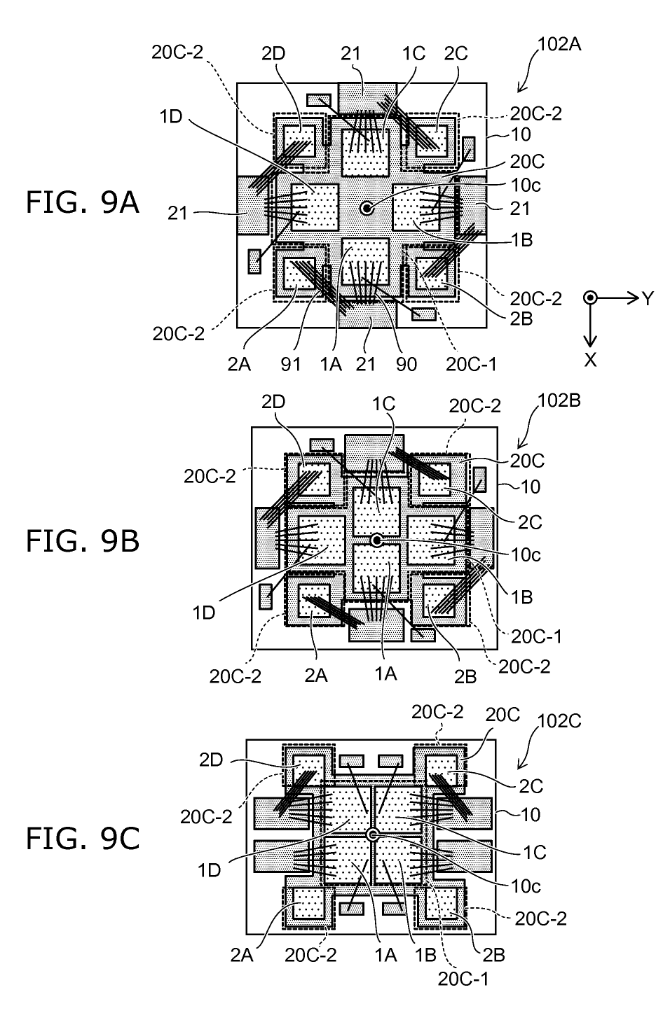

FIG. 9A is a schematic plan view of a power semiconductor module according to the third embodiment, FIG. 9B is a schematic plan view of the power semiconductor module according to the third embodiment, and FIG. 9C is a schematic plan view of the power semiconductor module according to the third embodiment.

As in a power semiconductor module 102A illustrated in FIG. 9A, when viewing an interconnection layer 20C from the Z-direction, the interconnection layer 20C is provided with a pattern region 20C-1 where a plurality of switching elements 1A to 1D is disposed, and a pattern region 20C-2 where rectifier elements 2A to 2D are disposed. Here, the pattern region 20C-2 is disposed on the outer side of the pattern region 20C-1. In other words, in the power semiconductor module 102A, the pattern region 20C-1 and the pattern region 20C-2 are provided individually in the interconnection layer 20C.

Even in this type of configuration, noise generation is suppressed by an operation similar to that as the first embodiment.

Furthermore, as in a power semiconductor module 102B illustrated in FIG. 9B, the four switching elements 1A to 1D provided on the pattern region 20C-1 may be disposed so that the distance between the switching element 1A and the switching element 1D may be shorter than the distance between the switching element 1C and the switching element 1D. In this case, the point P described above is disposed in line symmetry with the center point 10c.

Even in this type of configuration, noise generation is suppressed by an operation similar to that as the first embodiment. In addition, with the power semiconductor module 102B, the size of the power semiconductor module is reduced more than the power semiconductor module 102A.

Furthermore, as in a power semiconductor module 102C illustrated in FIG. 9C, the four switching elements 1A to 1D provided on the pattern region 20C-1 may be disposed in a grid pattern.

Even in this type of configuration, noise generation is suppressed by an operation similar to that as the first embodiment. In addition, with the power semiconductor module 102C, the size of the power semiconductor module is reduced more than the power semiconductor module 102B.

### FOURTH EMBODIMENT

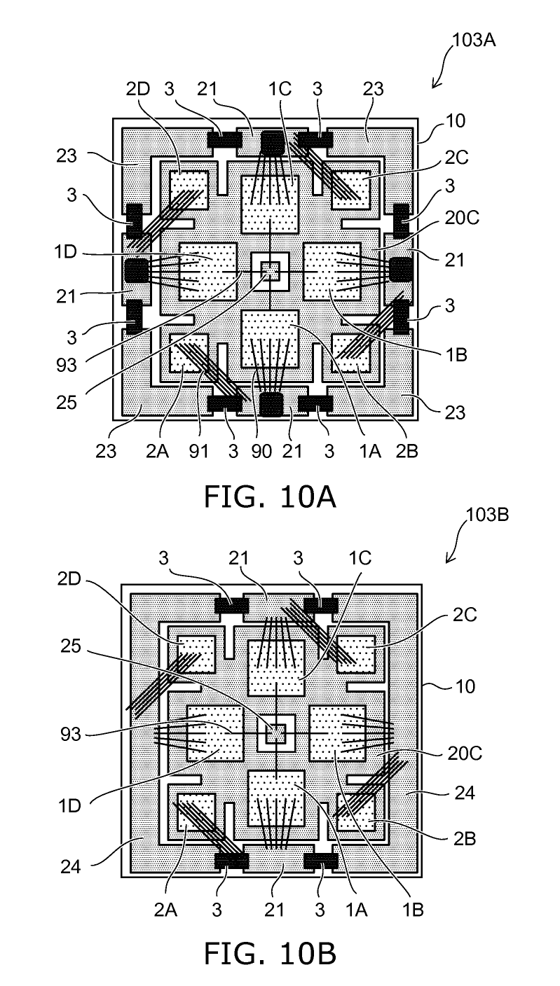

FIG. 10A is a schematic plan view of a power semiconductor module according to the fourth embodiment, and FIG. 10B is a schematic plan view of the power semiconductor module according to the fourth embodiment.

In a power semiconductor module 103A illustrated in FIG. 10A, the interconnection layer 20C is surrounded by the interconnection layer 21 and an interconnection layer 23. An emitter electrode 1e of the switching element 1C is connected to the interconnection layer 21 in line with the switching element 1C via the wire 90. Further, an emitter electrode 1e of the switching element 1A is connected to the interconnection layer 21 in line with the switching element 1A via the wire 90.

In the power semiconductor module 103A, a resistance element 3 is provided between the interconnection layer 21 and the interconnection layer 23 on the substrate 10. In other words, the resistance element 3 is connected to the emitter electrodes 1e of the two switching elements selected from the plurality of switching elements.

Here, in the power semiconductor module 103A, an interconnection layer 25 is provided in the center of the substrate 10 to suppress noise generation, and all of the emitter electrodes 1e of the switching elements 1A to 1D are connected to the interconnection layer 25 via wires 93. Each of the wires 93 is disposed in point symmetry from the center of the interconnection layer 25. Further, positions of each of the interconnection layer 21, the interconnection layer 23, and the resistance element 3 are in point symmetry from the center of the interconnection layer 25.

The resistance element 3 is a loss resistance element that can reduce the noise described above and convert it into heat. In other words, the noise carried in the interconnection layers 21 and 23 from the emitter electrode 1e is reduced by the resistance element 3. Providing the resistance element 3 in this manner allows the noise to be further suppressed.

Furthermore, because the resistance element 3 is disposed in point symmetry from the center of the interconnection layer 25, the heat generated in the resistance element 3 is uniformly dispersed in the power semiconductor module 103A.

Further, as in a power semiconductor module 103B illustrated in FIG. 10B, an interconnection layer 24 with the interconnection layer 21 and the interconnection layer 23 integrated may be provided. In this case, the resistance element 3 is connected between the interconnection layer 21 and the interconnection layer 24. With this type of configuration, the noise is also further suppressed.

### FIFTH EMBODIMENT

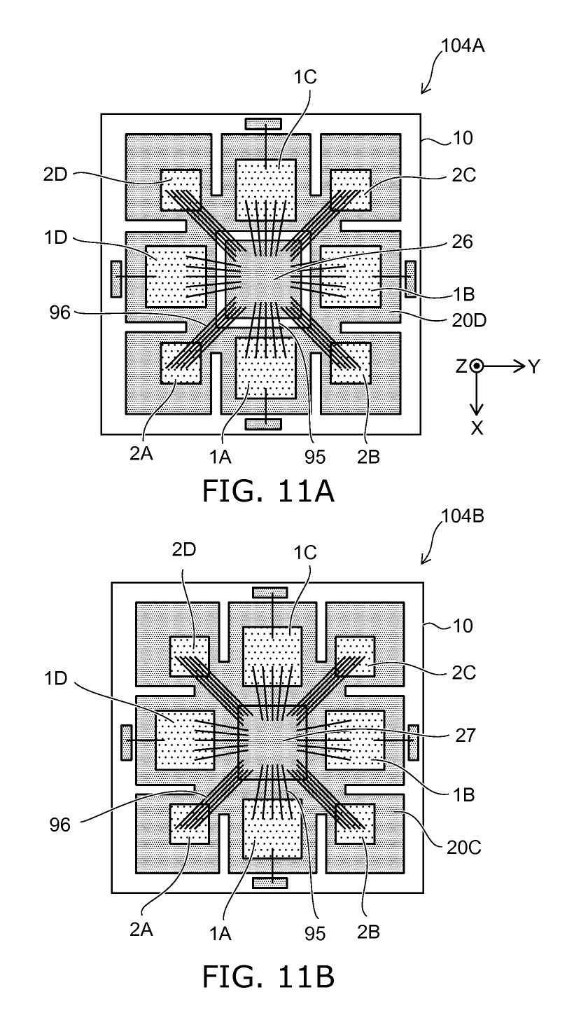

FIG. 11A is a schematic plan view of a power semiconductor module according to the fifth embodiment, and FIG. 11B is a schematic plan view of the power semiconductor module according to the fifth embodiment.

In the power semiconductor module 104A illustrated in FIG. 11A, an interconnection layer 26 is provided on the substrate 10 in the central portion of the interconnection layer 20D, separated from the interconnection layer 20D. The external form of the interconnection layer 20D is, for example, the same as the interconnection layer 20C described above.

When viewing an interconnection layer 26 from the Z-direction, the interconnection layer 26 is surrounded by the interconnection layer 20D. Each of the emitter electrodes 1e of the plurality of switching elements 1A to 1D is connected to the interconnection layer 26 via wires 95. Furthermore, each of the anode electrodes 2a of the plurality of rectifier elements 2A to 2D is connected to the interconnection layer 26 via wires 96. In other words, each of the emitter electrodes 1e of the plurality of switching elements 1A to 1D and the anode electrodes 2a of the rectifier elements 2A to 2D connected in parallel to each of the plurality of switching elements are electrically connected in common to the interconnection layer 26.

Further, a power semiconductor module 104B illustrated in FIG. 11B is provided with an interconnection layer 27 in place of the interconnection layer 26. The interconnection layer 27 is provided on the interconnection layer 20C. An insulating layer (not illustrated in the figure) is provided between the interconnection layer 27 and the interconnection layer 20C.

Even in this type of configuration, noise generation is suppressed by an operation similar to that as the first embodiment. Further, disposing the interconnection layers 26 and 27 connected to the emitter electrode 1e in the central portion of the power semiconductor module allows the emitter electrode 1e to be easily removed.

Note that “point symmetry” and “line symmetry” used in the embodiment do not refer to point symmetry and line symmetry used in mathematics, and are at times used to mean substantial point symmetry and substantial line symmetry. In other words, a point disposed in point symmetry (or line symmetry) from a center point includes positions offset from the position disposed in point symmetry (or line symmetry) from the center point. That is to say, the positions of elements, interconnection layers, and wires may be offset in a small range. In this offset range, the power semiconductor module has the same working effect.

Although the embodiments are described above with reference to the specific examples, the embodiments are not limited to these specific examples. That is, design modification appropriately made by a person skilled in the art in regard to the embodiments is within the scope of the embodiments to the extent that the features of the embodiments are included. Components and the disposition, the material, the condition, the shape, and the size or the like included in the specific examples are not limited to illustrations and can be changed appropriately.

The components included in the embodiments described above can be combined to the extent of technical feasibility and the combinations are included in the scope of the embodiments to the extent that the feature of the embodiments is included. Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A power semiconductor module comprising:
a substrate;
a first interconnection layer provided on the substrate;
a plurality of semiconductor elements provided on the first interconnection layer, each of the semiconductor elements having a first electrode, a second electrode, and a third electrode, and the second electrode being electrically connected to the first interconnection layer; and
a rectifier element provided on the first interconnection layer, and the rectifier element including a fifth electrode electrically connected to the first interconnection layer and a fourth electrode electrically connected to the first electrode,
the semiconductor elements and the rectifier elements being radially disposed on the first interconnection layer from arbitrary first point in the substrate,
arbitrary points fallen in respective regions of the semiconductor elements being disposed in point symmetry or line symmetry based on the first point, and
arbitrary points fallen in a region of the rectifier element being disposed in point symmetry or line symmetry based on the first point.

2. The module according to claim 1, wherein the first interconnection layer is cross shaped,
the semiconductor elements include four semiconductor elements,
each of the four semiconductor elements is provided in each region of the first interconnection layer extending in four directions from the center of the cross shaped first interconnection layer, and
the rectifier element is provided on an outer side of the each of the four semiconductor elements.

3. The module according to claim 1, further comprising an electrode terminal in a center of the first interconnection layer.

4. The module according to claim 1, further comprising a third interconnection layer on the substrate,
the first electrode of any one of the semiconductor elements and the fourth electrode of the rectifier element being electrically connected via the third interconnection layer.

5. The module according to claim 4, further comprising an electrode terminal on the third interconnection layer.

6. The module according to claim 1, wherein, the first interconnection layer has first regions extending in four directions from a center of the first interconnection layer and second regions further extending from the first regions, configuring an L shape with the first regions,
the semiconductor elements include four semiconductor elements,
each of the four semiconductor elements is provided in each of the first regions, and
the rectifier element is provided in each of the second regions.

7. The module according to claim 6, further comprising one other rectifier element in line with the rectifier element,
the rectifier element and the one other rectifier element are connected in parallel.

8. The module according to claim 1, wherein the first interconnection layer has a region where the semiconductor elements are disposed and a region provided on an outer side of the region where the semiconductor elements are disposed and the rectifier element is disposed.

9. The module according to claim 1, further comprising a resistance element provided on the substrate,
the resistance element being connected between the first electrode of the one semiconductor elements selected from the semiconductor elements and the first electrode of the one other semiconductor elements selected from the semiconductor elements.

10. The module according to claim 9, wherein the resistance element is disposed on an outer side of the first interconnection layer.

11. The module according to claim 9, wherein the two semiconductor elements are arrayed in series, the two semiconductor elements being connected to the resistance element and the first point.

12. The module according to claim 9, further comprising a plurality of resistance elements,
the resistance elements are connected in series between the first electrode of the one semiconductor elements selected from the semiconductor elements and the first electrode of the one other semiconductor elements selected from the semiconductor elements.

13. The module according to claim 1, further comprising a second interconnection layer provided on the substrate,
the second interconnection layer is surrounded by the first interconnection layer, and
the first electrode of each of the semiconductor elements and the fourth electrode of the rectifier element connected in parallel to each of the semiconductor elements are electrically connected in common to the second interconnection layer.

14. The module according to claim 13, wherein the second interconnection layer is disposed to a center of the substrate.

15. The module according to claim 13, wherein the second interconnection layer is provided on the first interconnection layer with an insulating layer interposed.
